(19) United States
(12) Patent Application Publication
(10) Pub. No.: US 2008/0041619 A1
(43) Pub. Date: Feb. 21, 2008

(54) Component-embedded multilayer printed wiring board and manufacturing method thereof

(75) Inventors: Doo-Hwan Lee, Suwon-si (KR); Seung-Gu Kim, Suwon-si (KR); Won-Cheol Bae, Pyeongtaek-si (KR); Moon-Il Kim, Yuseong-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/889,498

(22) Filed: Aug. 14, 2007

(30) Foreign Application Priority Data
Aug. 17, 2006 (KR) 10-2006-0077530

(51) Int. Cl. H05K 1/16; H05K 3/36

(52) U.S. Cl. 174/260; 29/830

(57) ABSTRACT

A component-embedded multilayer printed wiring board and manufacturing method thereof. A component-embedded multilayer printed wiring board that includes: a first wiring board, in which a component is embedded; an intermediate layer which is stacked on the first wiring board and through which at least one conductive bump penetrates in correspondence to a wiring pattern formed on the first wiring board; and a second wiring board which is stacked on the intermediate layer and on a surface of which a wiring pattern is formed in correspondence with the conductive bump, can contribute to forming smaller and more functional electronic products, and by individually producing wiring boards having embedded components and then stacking these with intermediate layers interposed in-between, the defect status of each wiring board can be examined in advance, while this approach can be used in conjunction with existing surface mounting approaches to increase the effective mounting area.

### CROSS-REFERENCE TO RELATED APPLICATIONS

This application claims the benefit of Korean Patent Application No. 10-2006-0077530 filed with the Korean Intellectual Property Office on Aug. 17, 2006, the disclosure of which is incorporated herein by reference in its entirety.

### BACKGROUND

1. Technical Field

The present invention relates to a component-embedded multilayer printed wiring board and a manufacturing method thereof.

2. Description of the Related Art

The component-embedded printed wiring board is structured to have a component embedded inside a printed wiring board having multiple wiring pattern layers. Research and development are in progress focused on applying the component-embedded printed wiring board to advanced electronic products such as mobile equipment, etc., which is becoming smaller and being endowed with more functionality. Until now, it has mostly been used for flip chip mounting package boards or system in package boards, for electrical efficiency and convenient examining.

However, the effect of embedding a component in a board is generally maximized when a component is embedded in a printed wiring board, such as in the main board of a mobile equipment, which contributes greatly to the mobile product becoming smaller and more functional.

FIG. 1 is a cross-sectional view of a component-embedded multilayer printed wiring board according to prior art. An embedding process in related art is proceeded with by a method of processing a cavity through multiple wiring pattern layers and embedding a component in the cavity. In this conventional embedding process, the examination of a board can be performed only after the manufacture of the printed wiring board is complete. It is no more than merely adding a process of forming a cavity to the existing method of manufacturing a printed wiring board.

In addition, the conventional method of manufacturing a printed wiring board has a risk of low manufacturing efficiency, because it does not include the special processes that may be needed for embedding components, when more and more restrictions are being added, such as countermeasures for static electricity, and so on. Post-completion examination also makes it difficult to prepare countermeasures defects. Moreover, it may be difficult to optimize the design of wiring patterns, because in addition to the core layer, which serves as an active circuit for :the printed -wiring board, a build-up layer is used for electrically connecting to the embedded component.

### SUMMARY

An aspect of the present invention aims to provide component-embedded multilayer printed wiring board, and a method of manufacturing the component-embedded multilayer printed wiring board, which increases yield, resolves the problems of post-completion examination, and optimizes wiring pattern design, by performing a plurality of unit processes and then completing the component-embedded multilayer printed wiring board through a subsequent stacking process.

One aspect of the claimed invention provides a component-embedded multilayer printed wiring board that includes: a first wiring board, in which a component is embedded; an intermediate layer which is stacked on the first wiring board and through which at least one conductive bump penetrates in correspondence to a wiring pattern formed on the first wiring board; and a second wiring board which is stacked on the intermediate layer and on a surface of which a wiring pattern is formed in correspondence with the conductive bump. A component may be embedded also in the second wiring board.

The first wiring board may include multiple components having electrodes coupled on one side, where the electrode of at least one of the components may be embedded facing one side of the first wiring board, and the electrode of at least another of the components may be embedded facing the opposite side of the first wiring board. In this case, it may be desirable to have the number of components embedded with the electrode facing one side of the first wiring board be in correspondence with the number of components embedded with the electrode facing the other side of the first wiring board. Also, the arrangement of components embedded facing each side may be optimized according to the density of input and output terminals of those components using wiring and/or according to the number of components.

Another aspect of the claimed invention provides a method of manufacturing a component-embedded multilayer printed wiring board that includes producing a first wring board and a second wiring board, in which at least one component is embedded, and which have a wiring pattern formed on at least one surface; producing an intermediate layer by penetrating having at least one conductive bump through an insulating board in correspondence with the wiring pattern; and stacking the second wiring board on the first wiring board with the intermediate layer inserted in-between.

Producing the first wring board and the second wiring board may include forming an inner circuit on a surface of a core board and processing a cavity in the core board in correspondence to a position where the component is to be embedded; stacking tape on a side of the core board and mounting the component on the tape by inserting the component in the cavity onto the tape from the opposite side of the core board; stacking an insulating layer on the opposite side of the core board, removing the tape, and afterwards stacking the insulating layer on a side of the core board; and forming the wiring pattern on at least one surface of the insulation layer.

Producing the intermediate layer may include forming at least one conductive bump on the wiring board or on a separate supporting board by printing and hardening conductive paste; stacking the insulating board on the supporting board or wiring board such that the conductive bump penetrates the insulating board; and removing the supporting board.

Stacking the second wiring board on the first wiring board with the intermediate layer inserted in-between may include aligning the first wiring board, the intermediate layer and the second wiring board such that the conductive bump and the wiring pattern are electrically connected; pressing the first wiring board and the second wiring board with the intermediate layer interposed in-between; and applying solder resist on at least one surface of the first wiring board and the second wiring board.

Yet another aspect of the claimed invention provides a method of manufacturing a component-embedded multilayer printed wiring board that includes producing a first wring board and a second wiring board, in which at least one component is embedded, and which have a wiring pattern formed on at least one surface; forming at least one conductive bump on the first wiring board by printing conductive paste on the first wiring board in correspondence with the wiring pattern; stacking an insulating board on the first wiring board such that the conductive bump penetrates the insulating board; and stacking the second wiring board on the insulating board such that the first wiring board and the second wiring board are electrically connected by the conductive bump.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a component-embedded multilayer printed wiring board according to prior art.

FIG. 2 is cross-sectional view of a component-embedded multilayer printed wiring board according to an embodiment of the present invention.

FIG. 3A is a flowchart illustrating a method of manufacturing a component-embedded multilayer printed wiring board according to an embodiment of the present invention.

FIG. 3B is a flowchart illustrating a method of manufacturing a component-embedded multilayer printed wiring board according to another embodiment of the present invention.

FIG. 4A, FIG. 4B, FIG. 4C, and FIG. 4D are diagrams illustrating a process of manufacturing a component-embedded multilayer printed wiring board according to an embodiment of the present invention.

FIG. 5A, FIG. 5B, FIG. 5C, and FIG. 5D are diagrams illustrating a process of manufacturing a component-embedded multilayer printed wiring board according to another embodiment of the present invention.

FIG. 6A, FIG. 6B, FIG. 6C, FIG. 6D, and FIG. 6E are diagrams illustrating a process of manufacturing a component-embedded multilayer printed wiring board according to an embodiment of the present invention.

FIG. 7A, FIG. 7B, and FIG. 7C are diagrams illustrating a process of manufacturing an intermediate layer according to an embodiment of the present invention.

FIG. 8A and FIG. 8B are diagrams illustrating a process of manufacturing an intermediate layer according to another embodiment of the present invention.

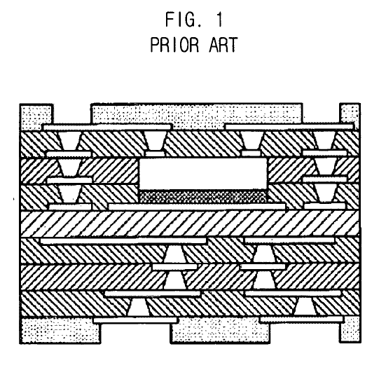

### DETAILED DESCRIPTION

The component-embedded multilayer printed wiring board and manufacturing method thereof according to certain embodiments of the invention will be described below in more detail with reference to the accompanying drawings, in which those components are rendered the same reference numeral that are the same or are in correspondence, regardless of the figure number, and redundant explanations are omitted.

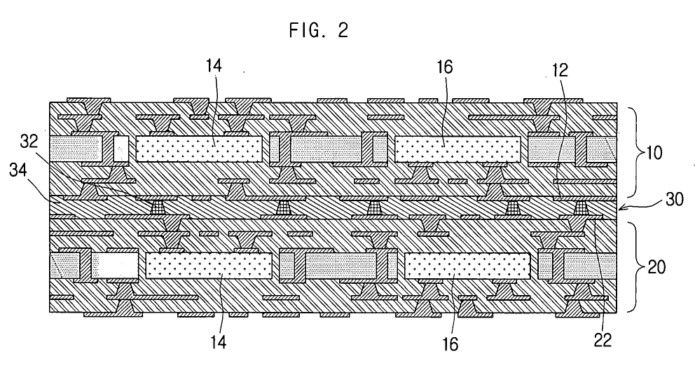

FIG. 2 is cross-sectional view of a component-embedded multilayer printed wiring board according to an embodiment of the present invention. A first wiring board 10, wiring patterns 12, 22, components 14, 16, a second wiring board 20, an intermediate layer 30, conductive bumps 32, and an insulating board 34 are shown in FIG. 2.

The present embodiment provides a component-embedded multilayer printed wiring board formed by producing component-embedded wiring boards individually and stacking them with B2it (Buried Bump Interconnection Technology).

“B2it” is a technology that enables boards or layers to be stacked simply and easily in which paste is printed on a supporting board, such as a copper foil, etc., to form bumps, and an insulating board is stacked on to produce a paste bump board. B2it can be applied not only to the stacking process for a multilayer board, but also to the manufacturing of the intermediate layer 30 inserted between boards as in the present embodiment.

Some of the components 14, 16 embedded in the wiring board may be embedded “face up”, i.e. having the electrodes face one direction, while the others may be embedded “face down”, i.e. with the electrodes facing the other direction, so that the wiring patterns for electrical connection with the components 14, 16 may be arranged evenly on both sides of the board, whereby an optimum design of wiring arrangement is possible, while the mechanical properties, such as stiffness and warpage resistance, etc., of the embedding board may be improved as well.

That is to say, according to the present embodiment, a printed wiring board can be manufactured by separately manufacturing two boards, i.e. the first wiring board 10 and the second wiring board 20, in which the components 14, 16 are embedded, and then stacking the wiring boards with the intermediate layer 30 inserted in-between. The intermediate layer 30 may be interposed between the first wiring board 10 and the second wiring board 20 and may serve to insulate the wiring pattern 12 formed on the surface of the first wiring board 10 and the wiring pattern 22 formed on the surface of the second wiring board 20, while providing an electrical passage in the necessary portions.

So, the intermediate layer 30 may be made with the insulating board 30 as a base, with conductive bumps 32 penetrating certain portions of the insulating board 34. The positions penetrated by the conductive bumps 32 may be where electrical connection is needed between the first wiring board 10 and the second wiring board 20. That is, the conductive bumps 32 penetrating the intermediate layer 30 may be mounted on the insulating board 34 in positions where electrical connection is needed between the wiring patterns 12, 22 formed on surfaces of the first wiring board 10 and the second wiring board 20.

The conductive bump 32 may be a type of “pillar” shaped structure made of a conductive material, and formed such that it penetrates the insulating board 34 to be exposed at both sides of the insulating board 34. The conductive bumps 32 penetrating the insulating board 34 can be formed by applying the so-called “Cu post” process, which is to form electrical connections by forming copper bumps on the electrodes of a component.

The component 14, 16, such as an IC, etc., embedded in the wiring board may be structured to have an electrode on one side of component. In embedding the component 14, 15 in the board, the wiring patterns may be designed on the surface of the board corresponding with the electrodes of the component 14, 16 such that there is electrical connection between the component and the board. Thus, in the process of embedding the component 14, 16, the design of the wiring patterns formed on the wiring boards may depend on which direction the electrodes face. For example, if the electrodes of all of the components face downward, the wiring pattern may be designed to be concentrated on the downward surface of the wiring board, whereas if the electrodes of all of the components face upward, the wiring pattern may be designed to be concentrated on the upward surface of the wiring board.

In the present embodiment, if multiple components 14, 16 are embedded in the first wiring board 10 and/or the second wiring board 20, some of the components 14, 16 may be embedded with the electrodes facing one side of the first wiring board, while others may be embedded with the electrodes facing the opposite side of the wiring board. Accordingly, as the wiring patterns for electrical connection to the components 14, 16 may be arranged evenly across both sides of the wiring board, the wiring pattern design can be optimized. Furthermore, as the wiring patterns may thus be arranged over both sides of the wiring board, there is a greater possibility that the mechanical strength, such as stiffness and warpage resistance, may be improved.

For example, in the case that two components 14, 16 are embedded each in the first wiring board 10 and the second wiring board 20, as shown in FIG. 2, by embedding one of the components 14 with the electrodes facing one side of the first wiring board and the electrode of the other component 16 with the electrodes facing the opposite side of the first wiring board, in other words, by making the number of components embedded with the electrode facing one side of the first wiring board equal the number of components embedded with the electrode facing the other side of the first wiring board, the effects of optimized wiring and increased stiffness mentioned above may be maximized.

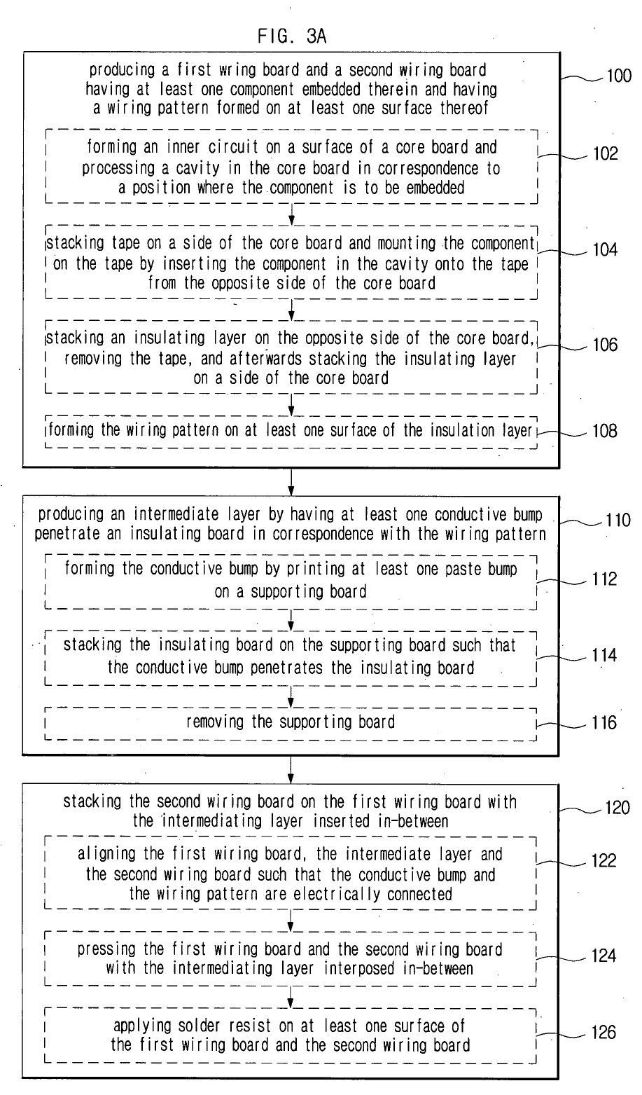

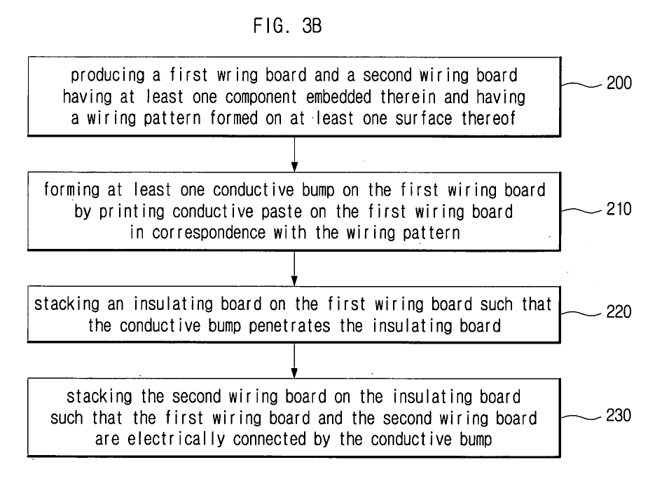

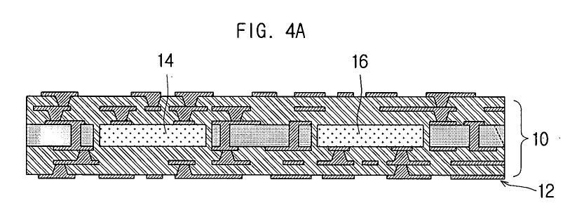

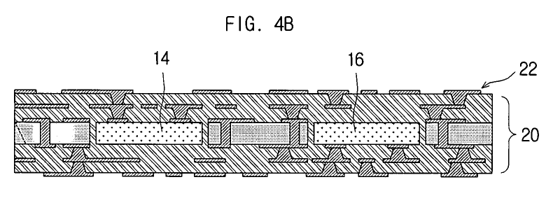

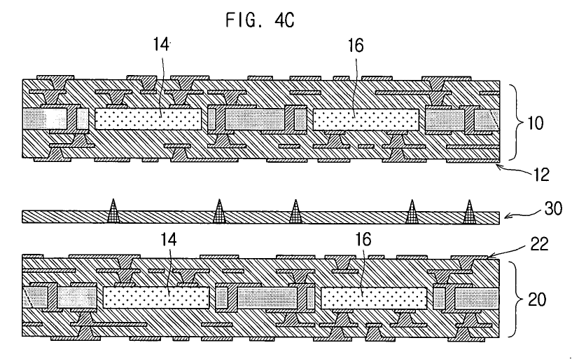

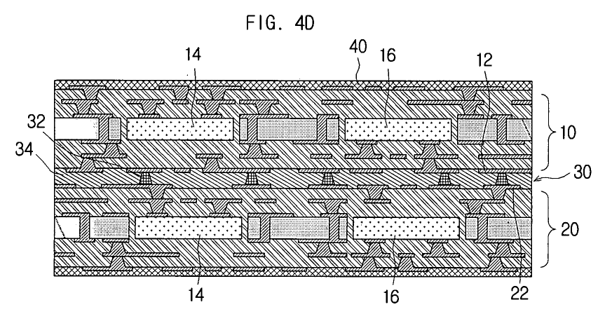

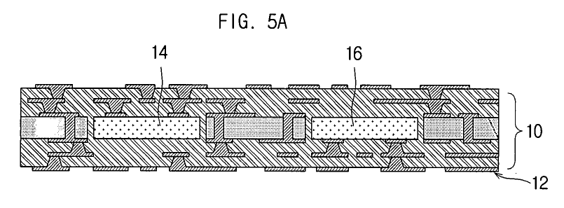

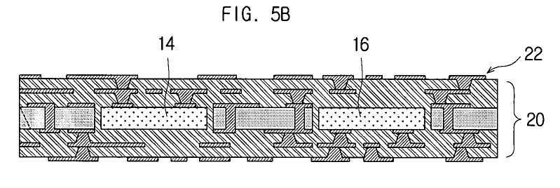

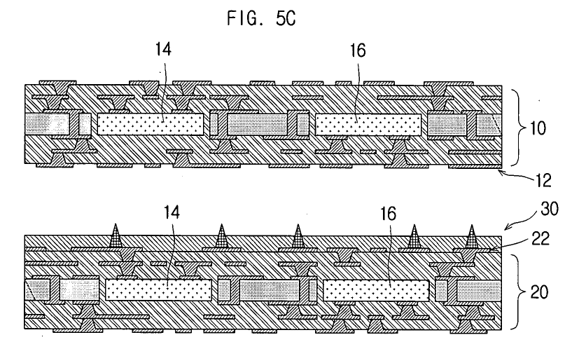

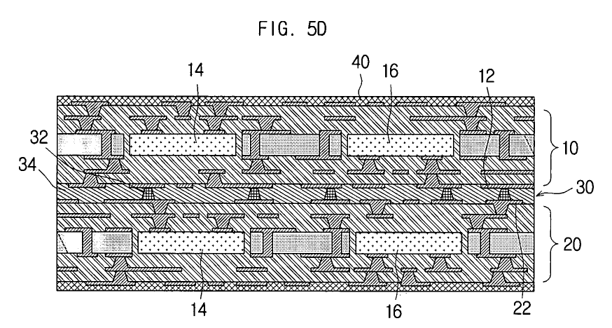

FIG. 3A is a flowchart illustrating a method of manufacturing a component-embedded multilayer printed wiring board according to an embodiment of the present invention, FIG. 3B is a flowchart illustrating a method of manufacturing a component-embedded multilayer printed wiring board according to another embodiment of the present invention, FIGS. 4A to 4D are diagrams illustrating a process of manufacturing a component-embedded multilayer printed wiring board according to an embodiment of the present invention, and FIGS. 5A to 5D are diagrams illustrating a process of manufacturing a component-embedded multilayer printed wiring board according to another embodiment of the present invention. First wiring boards 10, wiring patterns 12, 22, components 14, 16, second wiring boards 20, intermediate layers 30, conductive bumps 32, insulating boards 34, and solder resist 40 are illustrated in FIGS. 4A to 4D and FIGS. 5A to 5D.

As mentioned above, if each embedded board is produced individually and the board as a whole is manufactured by stacking them afterwards, the performance of each embedding board can be examined in an intermediate state, and the complete product can be examined again finally, whereby defects can be minimized in the final product and yield can be maximized.

Here, the wiring board may be produced individually through a process line, in which those elements that may be harmful to the components 14, 16, such as static electricity, are removed. That is, after embedding the components 14, 16 in the core layer and stacking wiring pattern boards on both sides to minimize warpage of the board, the design of optimum wiring patterns may be proceeded with, as described above.

To produce a printed wiring board according to the present embodiment, the first wiring board 10 and the second wiring board 20 may first be produced (100), which have components 14, 16 embedded inside and wiring patterns 12, 22 formed on the surface, as shown in FIGS. 4A and 4B and FIGS. 5A and 5B. The unit processes for embedding the components 14, 16 in each wiring board and forming wiring patterns 12, 22 will be described later.

Also, an intermediate layer 30 may be produced (110), to which conductive bumps 32 may be coupled that penetrate an insulating board 34 at positions requiring electrical connection, in correspondence with the opposing wiring patterns 12, 22 of the first wiring board 10 and the second wiring board 20. In some cases, the supporting board may be etched, after forming these conductive bumps 32 on the supporting board and penetrating the conductive bumps 32 through the insulating board. The unit process for producing the intermediate layer 30 by penetrating insulating board 34 with conductive bumps 32 will be described later.

Alternatively, as disclosed in FIG. 3B and FIGS. 5A to 5D, instead of producing the intermediate layer separately, it is possible to produce the first and second wiring boards that have components embedded and wiring patterns formed on the surfaces (200), print conductive paste on the surface of one of the first and second wiring boards to form conductive bumps (210), stack an insulation board such that the conductive bumps penetrate the insulation board to from an intermediate layer corresponding to the intermediate layer described above (220), and then stack the other of the first or second wiring boards to electrically connect the two wiring boards.

After the manufacturing of the first wiring board 10, the second wiring board 20, and an intermediate layer 30 is complete, the second wiring board 20 may be stacked on the first wiring board 10 with the intermediate layer inserted in-between (120), as shown in FIG. 4C. It is also possible, as described above, to form an intermediate layer 30 by forming conductive bumps 32 in correspondence to the wiring patterns of the first wiring board 10 or the second wiring board 20 and having the conductive bumps 32 penetrate an insulating board, and then proceeding with the stacking process while considering position alignment. As the conductive bumps 32 are made to penetrate the intermediate layer 30 in consideration of the wiring patterns 12, 22 formed on the surfaces of the first wiring board 10 and second wiring board 20, the first wiring board 10 and the second wiring board 20 may be connected electrically with each other.

The first wiring board 10, the intermediate layer 30, and the second wiring board 20 may be aligned such that the conductive bumps 32 of the intermediate layer 30 and the wiring patterns 12, 22 of the first wiring board 10 and the second wiring board 20 are electrically connected (122). As each of the wiring boards and the intermediate layer 30 have been manufactured in consideration of the electrical connection from the beginning of the manufacturing process, the wiring boards and the intermediate layer 30 may be aligned overall according to a certain reference point.

Next, the first wiring board 10 and the second wiring board 20 may be pressed together (124) to electrically connect the wiring patterns 12, 22 formed on the surface of each wiring board and the conductive bumps 32 penetrating the intermediate layer 30. In this process, the conductive bumps 32 may be altered in form, as shown in FIG. 4D, to improve the reliability of the electrical connection.

Lastly, a surface treatment process may be performed of applying solder resist 40 on the surface of the printed wiring board, that is, on each surface of the first wiring board 10 and the second wiring board 20, as shown in FIG. 4D, and of opening and gold plating portions where electrical connections to the exterior may be required. In this way, the manufacture of a component-embedded multilayer printed wiring board may be completed.

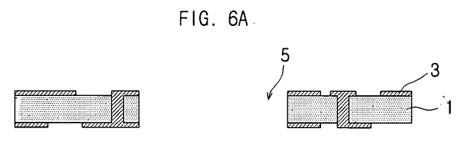

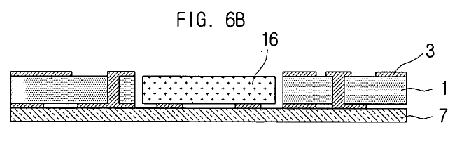

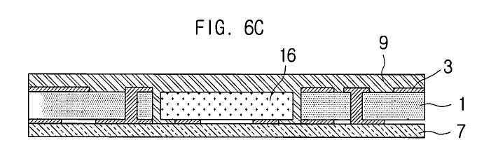

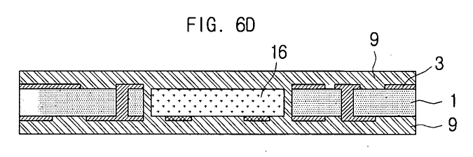

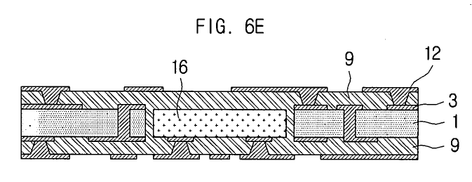

FIGS. 6A to 6E are diagrams illustrating a process of manufacturing a component-embedded mulfilayer printed wiring board according to an embodiment of the present invention. A core board 1, inner circuits 3, a cavity 5, tape 7, insulating layers 9, wiring patterns 12, and a component 16 are disclosed in FIGS. 6A to 6E.

To produce a unit board individually having a component 16 embedded and wiring patterns 12 formed on the surfaces, for manufacturing the afore-mentioned wiring board, i.e. a printed wiring board according to the present embodiment, inner circuits 3 may first be formed on the surfaces of the core board 1, and a cavity 5 may be processed, which is a kind of through-hole, in the position where the component 16 is to be embedded, as illustrated in FIG. 6A.

Next, as in FIG. 6B, tape 7 may be attached on one side of the core board 1, while the component 16 may be inserted in the cavity 5 onto the tape 7 from the opposite side of the core board (104). The tape 7 is an element which attaches to one side of the core board 1 and closes one side of cavity 5, and thus may be made of a material capable of such performance. It is apparent that heat-resistant dust-free tape may be used, in order that the tape 7 may endure the heat applied to the core board 1 during the build-up process and leave no impurities on the surfaces of the component 16 and the core board 1 during the process of removing the tape 7.

Next, as in FIG. 6C, an insulating layer 9 may be stacked and hardened on the opposite side of the core board 1, to fill up the cavity 5 space in which the component 16 is embedded, and a build-up layer may be stacked for forming outer circuits on the core board 1. Next, as in FIG. 6D, the tape attached on one side of core board 1 may be removed, after which an insulating layer 9 may be stacked and hardened (106), so that a build-up layer may be stacked on the one side of the core board 1 also. A cleaning process can be performed before stacking the insulating layer 9, to remove impurities remaining on the surface of core board 1 after removing the tape 7.

Lastly, wiring patterns 12 may be formed on the surfaces of the insulating layers 9 stacked on either side of the core board 1 having an embedded component 16, as in FIG. 6E, to complete the manufacture of the wiring board.

In the above process of manufacturing a wiring board, that is, in the process of embedding the component 16 in the core board 1 and forming the wiring patterns 12 on the core board 1, the wiring patterns 12 formed on both sides of the core board 1 can be designed to be evenly distributed, by making the thickness of the insulating layers 9 uniform on either side of the core board 1, embedding multiple components 16 horizontally as shown in FIGS. 4A to FIG. 4D or FIGS. 5A to 5D, and embedding some components 16 face up and others face down.

For example, in the case where the component 16 is embedded face down, as in FIGS. 6A to 6E, it may be advantageous that an additionally embedded component be embedded horizontally and face up, to proceed with a process of manufacturing a printed wiring board according to the present embodiment as in FIGS. 4A to 4D.

The design of wiring patterns 12 connected electrically to the components 16 may become more and more complicated with increased numbers of embedded components 16, and with greater complexity of the wiring patterns 12, the number of build-up layers stacked on either side of the core board 1 may also be increased. As described above, after the final completion of the manufacture of the wiring board, electrical examination of each component embedded in the board can be performed, utilizing the pads, etc., used in the process of forming the wiring patterns 12.

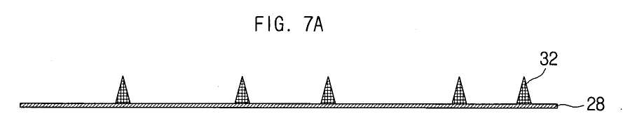

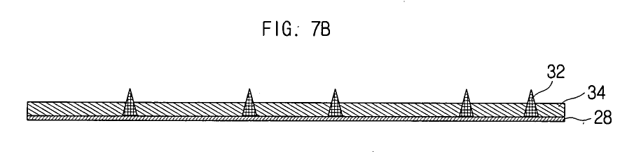

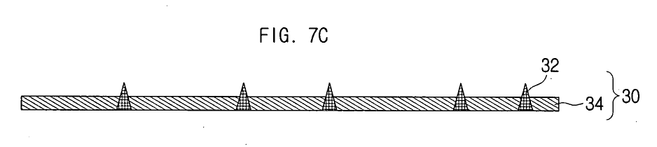

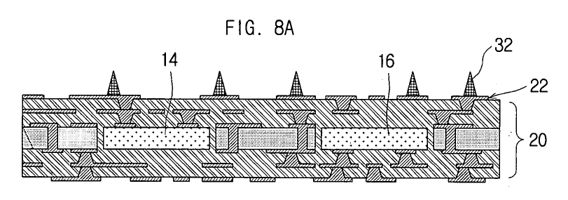

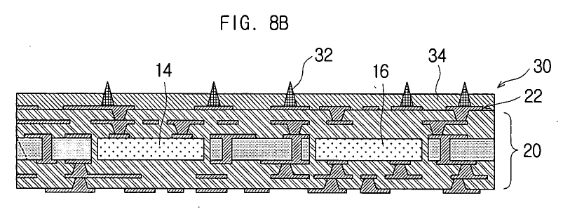

FIGS. 7A to 7C are diagrams illustrating a process of manufacturing an intermediate layer according to an embodiment of the present invention, and FIGS. 8A and 8B are diagrams illustrating a process of manufacturing an intermediate layer according to another embodiment of the present invention. A supporting board 28, an intermediate layer 30, conductive bumps 32, and an insulating board 34 are disclosed in FIGS. 7A to 7C and FIGS. 8A to 8B.

After producing individually the unit boards used for manufacturing the wiring board described with reference to FIGS. 6A to 6E, that is, the printed wiring board according to the present embodiment, these component-embedded wiring boards made individually may be stacked and electrically connected, to finally manufacture a printed wiring board according to this embodiment.

In this embodiment, an intermediate layer 30 may be used in the process of stacking and electrically connecting the wiring boards, where the intermediate layer 30 may be structured, as described above, to have conductive bumps 32 penetrating an insulating board 34. As mentioned above, the method of manufacturing the intermediate layer 30 may include such processes as the “B2it” process of penetrating an insulating material with hardened conductive paste, the method of applying solder resist and utilizing solder bumps, and the so-called “Cu post” process of building copper layers as columns to implement electrical passages. The description below will illustrate an example of manufacturing an intermediate layer 30 employing the “B2it” process.

First, as in FIG. 7A, paste bumps may be printed and hardened on the supporting board 28 to form the conductive bumps 32 (112). The conductive bumps 32, as described above, may be formed in positions where electrical connection may be required between the wiring boards.

The supporting board 28 may be made from copper foil, etc., in order that it may be used afterwards as a wiring pattern, but in the present embodiment, the supporting board 28 may be an element that is removed after stacking the insulating board 34, and thus may be made from a material offering structural support on which to print the conductive paste.

Next, as in FIG. 7B, the insulating board 34 may be stacked on the supporting board 28 (114). In this process, portions of the paste bumps, i.e. the conductive bumps 32, may penetrate the insulating board 34 and protrude out over the surface of the insulating board 34. As the conductive bumps 32 may penetrate the insulating board 34 and be exposed, the intermediate layer 30 can serve to electrically connect the wiring boards stacked on either side.

In order for the conductive bumps 32 to penetrate the insulating board 34, the material of the conductive paste may have a hardness greater than that of the insulating board 34.

After the conductive bumps 32 are coupled to penetrate the insulating board 34, the supporting board 28 used for printing the paste bumps may be removed (116), to complete the production of the intermediate layer 30.

As described earlier, in order to omit the process that uses the supporting board 28, conductive paste may be printed on the wiring patterns where the first wiring board 10 or second wiring board 20 are connected to form conductive bumps 32, as in FIG. 8A, and an insulating board 34 may be placed such that it is penetrated by the conductive bumps 32, as in FIG. 8B, to complete the production of the intermediate layer 30.

According to certain embodiments of the invention as set forth above, electronic products can be given smaller sizes and greater functionality by having components embedded inside the printed wiring board. Also, by individually producing wiring boards having embedded components and then stacking these with intermediate layers interposed in-between, the defect status, etc., of each wiring board can be examined in advance, to maximize manufacturing yield. Each embedded board can also serve as an interposer.

In addition, by embedding multiple components in the wiring boards symmetrically in face up or face down configurations, and forming wiring patterns in portions corresponding to the electrodes of each component, the arrangement of wiring patterns can be optimized and the warpage of wiring patterns can be minimized.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A component-embedded multilayer printed wiring board comprising:
a first wiring board having a component embedded therein;
an intermediate layer stacked on the first wiring board and having at least one conductive bump penetrating therethrough in correspondence to a wiring pattern formed on the first wiring board; and
a second wiring board stacked on the intermediate layer and having a wiring pattern formed on a surface thereof in correspondence with the conductive bump.

2. The component-embedded multilayer printed wiring board of claim 1, wherein a component is embedded in the second wiring board.

3. The component-embedded multilayer printed wiring board of claim 1, wherein the first wiring board comprises a plurality of components having electrodes coupled on one side,
the electrode of at least one of the components embedded facing one side of the first wiring board, and
the electrode of at least another of the components embedded facing the opposite side of the first wiring board.

4. The component-embedded multilayer printed wiring board of claim 3, wherein the number of the components embedded with the electrode facing one side of the first wiring board is in correspondence with the number of the components embedded with the electrode facing the other side of the first wiring board.

5. A method of manufacturing a component-embedded multilayer printed wiring board, the method comprising: producing a first wring board and a second wiring board having at least one component embedded therein and having a wiring pattern formed on at least one surface thereof; producing an intermediate layer by having at least one conductive bump penetrate an insulating board in correspondence with the wiring pattern; and
stacking the second wiring board on the first wiring board with the intermediate layer inserted in-between.

6. The method of claim 5, wherein producing the first wring board and the second wiring board comprises:
forming an inner circuit on a surface of a core board and processing a cavity in the core board in correspondence to a position where the component is to be embedded; and
stacking tape on a side of the core board and mounting the component on the tape by inserting the component in the cavity onto the tape from the opposite side of the core board;
stacking an insulating layer on the opposite side of the core board, removing the tape, and afterwards stacking the insulating layer on a side of the core board; and
forming the wiring pattern on at least one surface of the insulation layer.

7. The method of claim 5, wherein producing the intermediate layer comprises:
forming the conductive bump by printing at least one paste bump on a supporting board;
stacking the insulating board on the supporting board such that the conductive bump penetrates the insulating board; and
removing the supporting board.

8. The method of claim 5, wherein the stacking comprises:
aligning the first wiring board, the intermediate layer and the second wiring board such that the conductive bump and the wiring pattern are electrically connected;
pressing the first wiring board and the second wiring board with the intermediate layer interposed in-between; and
applying solder resist on at least one surface of the first wiring board and the second wiring board.

9. A method of manufacturing a component-embedded multilayer printed wiring board, the method comprising:
producing a first wring board and a second wiring board having at least one component embedded therein and having a wiring pattern formed on at least one surface thereof;
forming at least one conductive bump on the first wiring board by printing conductive paste on the first wiring board in correspondence with the wiring pattern;
stacking an insulating board on the first wiring board such that the conductive bump penetrates the insulating board; and
stacking the second on the insulating board wiring board such that the first wiring board and the second wiring board are electrically connected by the conductive bump.
